(19) United States
(12) Patent Application Publication
(10) Pub. No.: US 2012/0327546 A1
(43) Pub. Date: Dec. 27, 2012

(54) ELECTRONIC APPARATUS

(76) Inventors: Tetsunari Ichimura, Ome-shi (JP); Takayuki Ochiai, Ome-shi (JP)

(21) Appl. No.: 13/416,287

(22) Filed: Mar. 9, 2012

(30) Foreign Application Priority Data
Jun. 22, 2011 (JP) 2011-138947

(51) Int. Cl. H02H 3/08; H05K 7/14

(52) U.S. Cl. 361/93.1; 307/149

(57) ABSTRACT

According to one embodiment, an electronic apparatus includes a first terminal on a first board, a second terminal on a second board, a connection member configured to transmit signals between the first board and the second board, the connection member including a wire rod member including kinds of wire rods, a first connector capable of being connected to the first terminal and the second terminal, and a second connector capable of being connected to the first terminal and the second terminal, wherein at least one of the signals is not transmitted when the first connector is connected to the second terminal and the second connector is connected to the first terminal.

### CROSS-REFERENCE TO RELATED APPLICATIONS

This application is based upon and claims the benefit of priority from prior Japanese Patent Application No. 2011-138947, filed Jun. 22, 2011, the entire contents of which are incorporated herein by reference.

### FIELD

Embodiments described herein relate generally to an electronic apparatus comprising a wiring harness.

### BACKGROUND

In general, in the fields of electronic apparatuses, such as personal computers and communication devices, a wiring harness is widely known as a mechanism for interconnecting electronic components. A wiring harness usually comprises conductors and a pair of connectors interposed between two insulating layers.

In order to achieve commonality of components, there are cases where the same connector is used as both of the pair of connectors. When a wiring harness using kinds of wire rods is installed in reverse, since electrical connection is established, there are cases where the electronic apparatus operates to some extent, and passes a pre-shipment inspection. Since this connection is not between assumed wire rods, however, a problem may appear after shipment.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view illustrating an exemplary configuration of an electronic apparatus of the embodiment.

FIG. 2 shows an exemplary internal configuration of a computer main body of the electronic apparatus of the embodiment.

FIG. 3 shows an exemplary configuration of a wiring harness of the electronic apparatus of the embodiment.

FIG. 4 shows an exemplary internal configuration of the computer main body of the electronic apparatus of the embodiment.

FIG. 5 shows an exemplary internal configuration of the computer main body of the electronic apparatus of the embodiment, in a case where the wiring harness is installed in reverse.

FIG. 6 shows an exemplary configuration of a wiring harness and each of a main substrate and an auxiliary substrate.

FIG. 7 shows an exemplary assignment of signals to a wiring harness.

FIG. 8 shows an exemplary configuration of a wiring harness and each of a main substrate and an auxiliary substrate when the wiring harness is installed in reverse.

FIG. 9 shows an exemplary connection state in a case where the wiring harness is installed in reverse.

FIG. 10 shows an exemplary assignment of signals to the wiring harness.

FIG. 11 shows an exemplary connection state in a case where the wiring harness is installed in reverse.

FIG. 12 shows an exemplary assignment of signals to the wiring harness.

FIG. 13 shows an exemplary connection state in a case where the wiring harness is installed in reverse.

### DETAILED DESCRIPTION

Various embodiments will be described hereinafter with reference to the accompanying drawings.

In general, according to one embodiment, an electronic apparatus, comprises a first printed wiring board, a second printed wiring board, a second terminal, and a connection member. The first terminal is disposed on the first printed wiring board. The second terminal is disposed on the second printed wiring board. The connection member configured to transmit signals between the first printed wiring board and the second printed wiring board. The connection member comprises a wire rod member comprising kinds of wire rods, a first connector capable of being connected to the first terminal and the second terminal, and a second connector capable of being connected to the first terminal and the second terminal. The signals are transmitted normally when the first connector is connected to the first terminal and the second connector is connected to the second terminal. At least one of the signals is not transmitted when the first connector is connected to the second terminal and the second connector is connected to the first terminal.

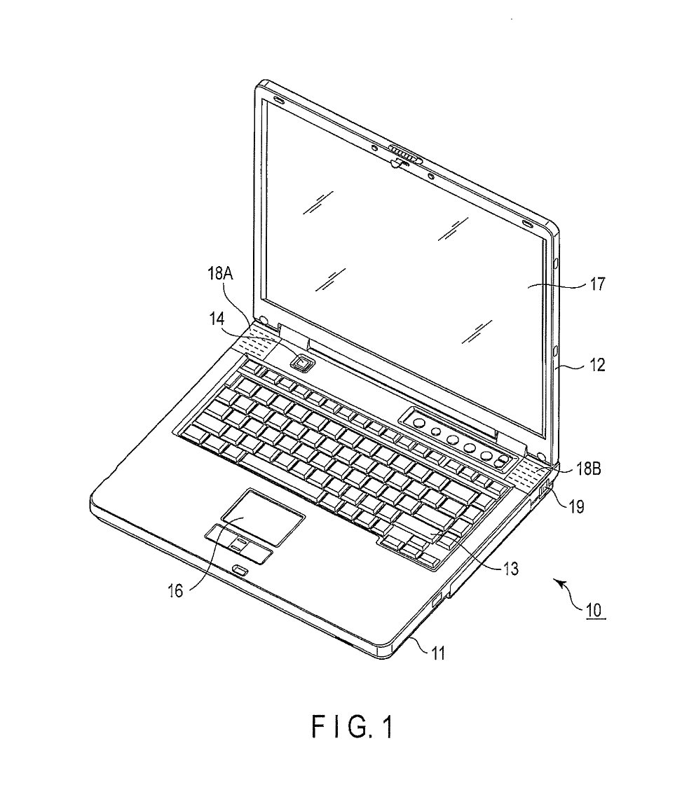

A configuration of an electronic apparatus according to an embodiment of the present invention will be described, with reference to FIG. 1. The electronic apparatus of the present embodiment is embodied as a notebook computer 10, which functions as an information processing apparatus, for example.

FIG. 1 is a perspective view of the computer 10 in a state in which a display unit is open. The computer 10 comprises a computer main body 11 and a display unit 12. A display device formed of a thin-film-transistor liquid crystal display (TFT-LCD) 17 is incorporated into the display unit 12.

The display unit 12 is attached to the computer main body 11 so as to be rotatable between an open position, in which an upper surface of the computer main body 11 is exposed, and a closed position, in which the upper surface of the computer main body 11 is covered. The computer main body 11 includes a flat, box-shaped housing, and a keyboard 13, a power button 14 for powering the computer 10 on and off, a touch pad 16, speakers 18A, 18B, and the like are provided on an upper surface thereof.

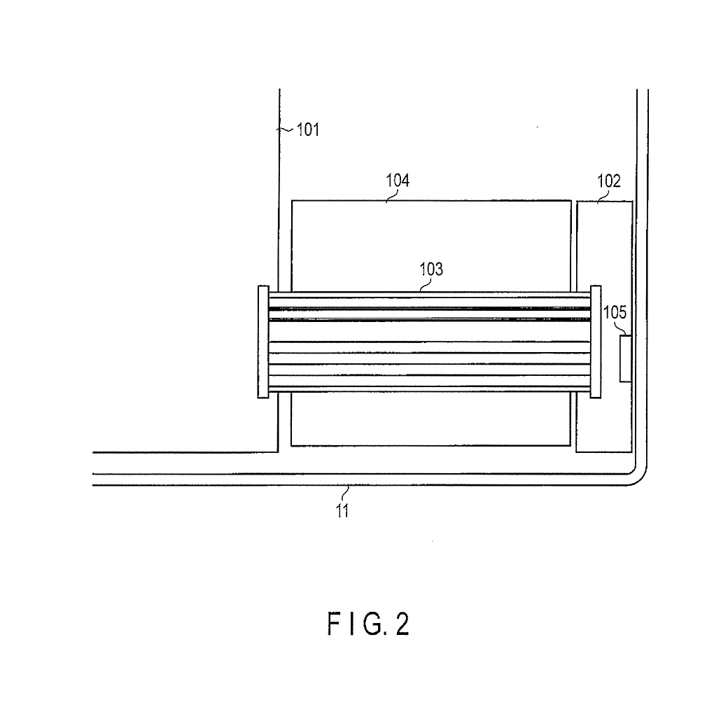

Next, an internal configuration of the computer main body 11 will be described with reference to FIG. 2.

As shown in FIG. 2, a main substrate (printed wiring board) 101, an auxiliary substrate (printed wiring board) 102, a wiring harness (connection member) 103, a hard disc drive (HDD) 104, and the like are provided inside the computer main body 11. A central processing unit (CPU), a memory controller hub (MCH), a main memory, an I/O controller hub (ICH), a graphics processing unit (GPU), a sound controller, a basic input/output system read only memory (BIOS-ROM), an embedded controller (EC/KBC), and the like are mounted on the main substrate. A USB connector 105 is provided on the auxiliary substrate. The main substrate 101 and the auxiliary substrate 102 are electrically connected via the wiring harness 103, and signals are transmitted between the main substrate 101 and the auxiliary substrate 102 via the wiring harness 103.

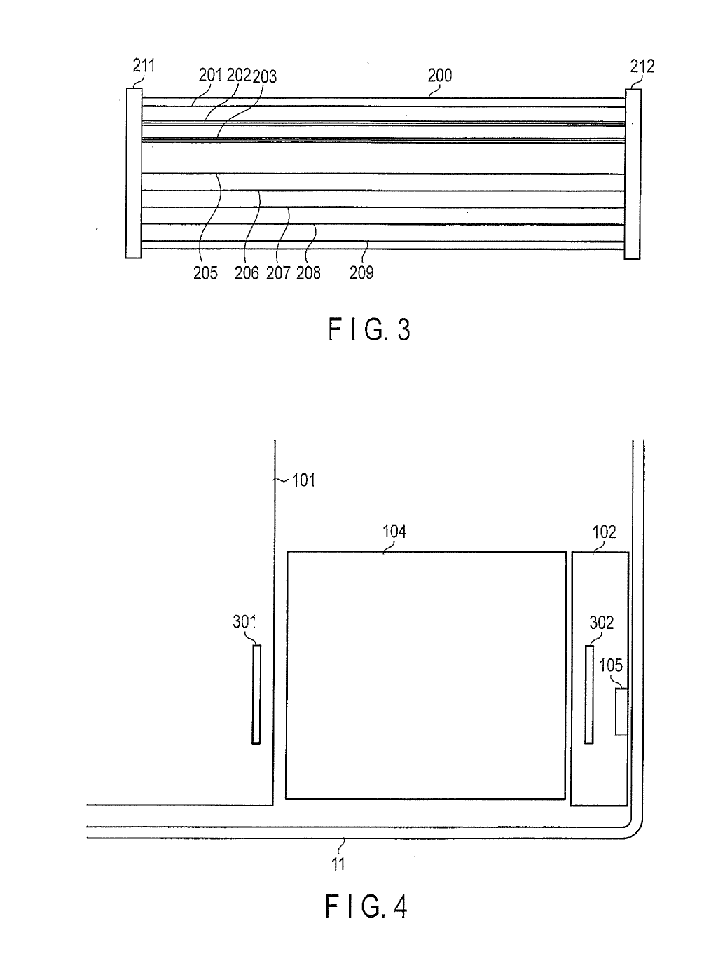

A configuration of the wiring harness 103 will be described with reference to FIG. 3. The wiring harness 103 includes a wire rod member 200, a first connector 211, a second connector 212, and the like. The wire rod member 200 includes a discrete wire 201, a coaxial wire 202, a coaxial wire 203, a discrete wire 205, a discrete wire 206, a discrete wire 207, a discrete wire 208, a discrete wire 209, and the like. The wire rod member 200 includes kinds of wire rods. Each of the first connector 211 and the second connector 212 includes 9 signal terminals. Of these pairs of signal terminals, 8 pairs excluding 1 pair are each formed of a first connector 211 and a second connector 212, for example. The wire rod member 200 is electrically connected by the discrete wire 201, the coaxial wire 202, the coaxial wire 203, the discrete wire 205, the discrete wire 206, the discrete wire 207, the discrete wire 208, and the discrete wire 209. The number of discrete wires and the coaxial wires is smaller than that of the signal terminals.

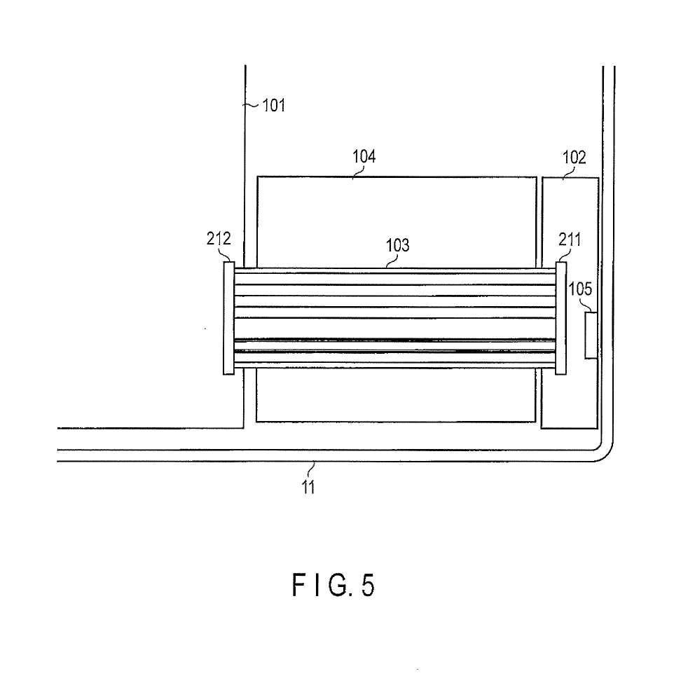

The first connector 211 is connected to a first terminal 301 provided on the main substrate 101, as shown in FIG. 4. The second connector 212 is connected to a second terminal 302 provided on the auxiliary substrate 102, as shown in FIG. 4. The first connector 211 can be connected to the second terminal 302. The second connector 212 can be connected to the first terminal 301.

When manufacturing the computer 10, there are cases where the first connector 211 is connected to the second terminal 302 and the second connector 212 is connected to the first terminal 301 by error, as shown in FIG. 5. In such a case, since electrical connection is established, there are cases where the computer 10 operates to some extent, and passes a pre-shipment inspection. Since this connection is not between assumed wire rods, however, a problem may appear after the shipment.

The computer 10 of the present embodiment is capable of detecting reverse connection by designing the pin assignment of the wiring harness 103 such that a specific function does not work when the wiring harness 103 is installed in reverse.

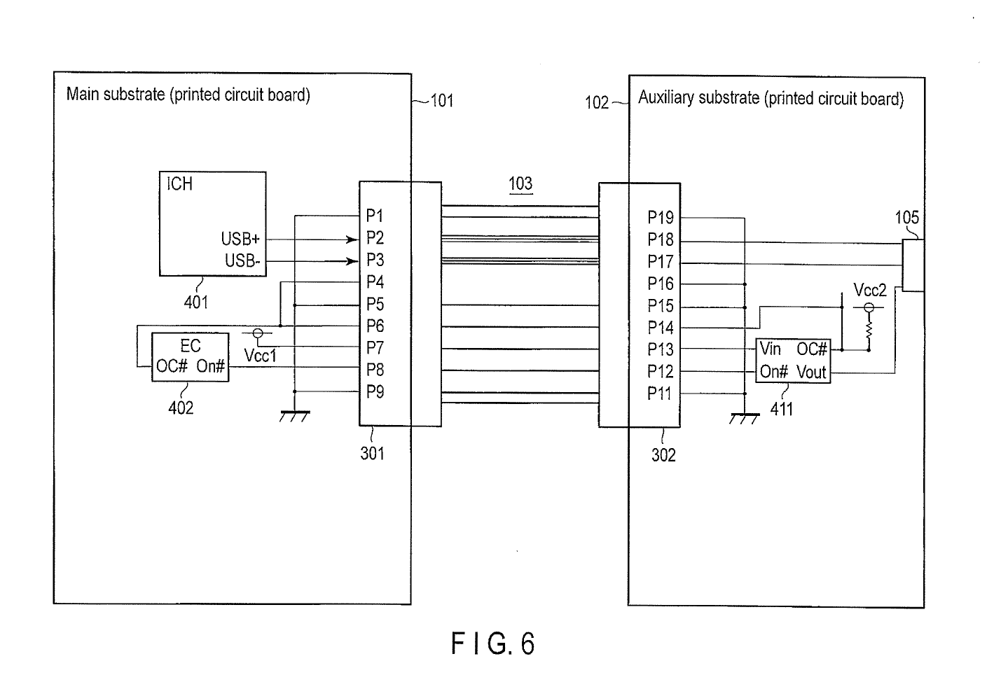

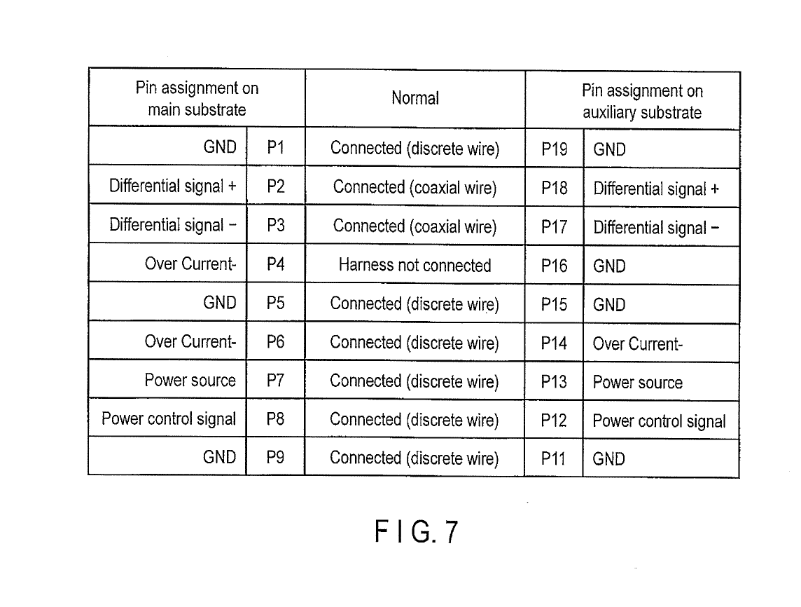

An exemplary assignment of signals (pin assignment) to the wiring harness 103 and an exemplary configuration of each of the substrates 101, 102 will be described, with reference to FIG. 6.

The ICH 401, the EC 402, and the first terminal 301 are provided on the main substrate 101. A current regulator IC 411, a second terminal 302, a USB connector 105, and the like, are provided on the auxiliary substrate 102.

Signal terminals P1 to P9 are provided at the first terminal 301. Signal terminals P11 to P19 are provided at the second terminal 302.

Signal terminals P1, P5, P9 of the first terminal 301 are ground terminals and are grounded. A pair of USB differential signals (differential signal + and differential signal −) is assigned to two signal terminals P2, P3. A pair of USB differential signals are differential signals transmitted bi-directionally between a USB controller provided in the ICH 401 and an external USB device. An overcurrent signal (Overcurrent −) (power potential Vcc2) is assigned to signal terminals P4, P6 of the first terminal 301. A power potential Vcc1 is assigned to signal terminal P7 of the first terminal 301. A power control signal (On# signal) output from the EC 402 is assigned to signal terminal P8 of the first terminal 301.

Signal terminals P11, P15, P16, P19 of the second terminal 302 are ground terminals and are grounded. A pair of USB differential signals (differential signal + and differential signal −) are assigned to the two signal terminals P17, P18. An overcurrent signal (Overcurrent −) (power potential Vcc2) is assigned to signal terminal P14 of the second terminal 302. A power potential Vcc1 is assigned to signal terminal P13 of the second terminal 302. A power control signal (On# signal) output from the EC 402 is assigned to signal terminal P2 of the second terminal 302.

When the wiring harness 103 is connected normally, the power potential Vcc1 is input to the current regulator IC 411, and the current regulator IC 411 outputs an output voltage Vout to the USB connector 105. When the wiring harness 103 is connected normally, an overcurrent signal (Overcurrent −) is input to the EC 402.

The EC 402 determines whether an overcurrent state is occurring or not in the auxiliary substrate 102, in response to the overcurrent signal OC#. In order to determine whether an overcurrent state is occurring or not, the EC 402 determines whether the overcurrent signal OC# is high. When the overcurrent signal OC# is determined to be high (i.e., an overcurrent state is not occurring), the EC 402 outputs a low On# signal. When the overcurrent signal OC# is determined not to be high (i.e., the overcurrent signal OC# is low and the overcurrent state is occurring), the EC 402 outputs a high On# signal.

The current regulator IC 411 outputs an output voltage Vout to the USB connector 105 when the On# signal is low, and does not output an output voltage Vout to the USB connector 105 when the On# signal is high.

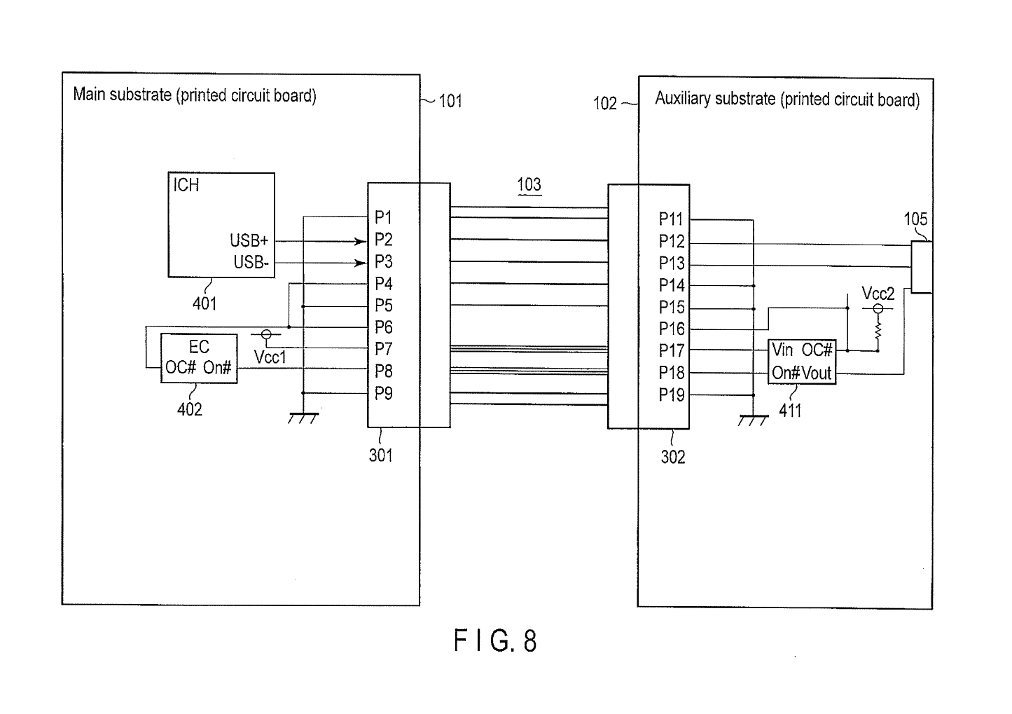

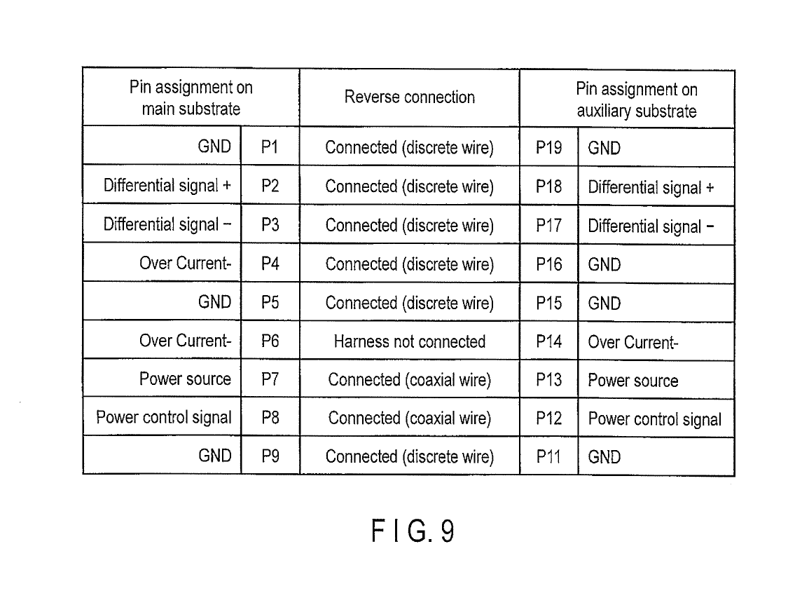

FIGS. 8 and 9 show a state in which the wiring harness 103 is installed in reverse. When the wiring harness 103 is connected in reverse, signal terminal P6 of the first terminal 301 and signal terminal P16 of the second terminal 302 are not electrically connected, and signal terminal P4 of the first terminal 301 and signal terminal P14 connected to the ground of the second terminal 302 are electrically connected. As a result, the OC# signal input to the EC 402 goes low. Since the OC# signal becomes smaller than the threshold value, the EC 402 recognizes this state as an overcurrent state.

The EC 402 outputs a high On# signal. The current regulator IC 411 stops outputting an output voltage VOUT in response to the On# signal going high. Thereby, a power source is not supplied to the USB connector 105. When the USB device is inserted into the USB connector 105 during a pre-shipment inspection, it is easily seen that the wiring harness 103 is connected in reverse, since the USB device does not operate.

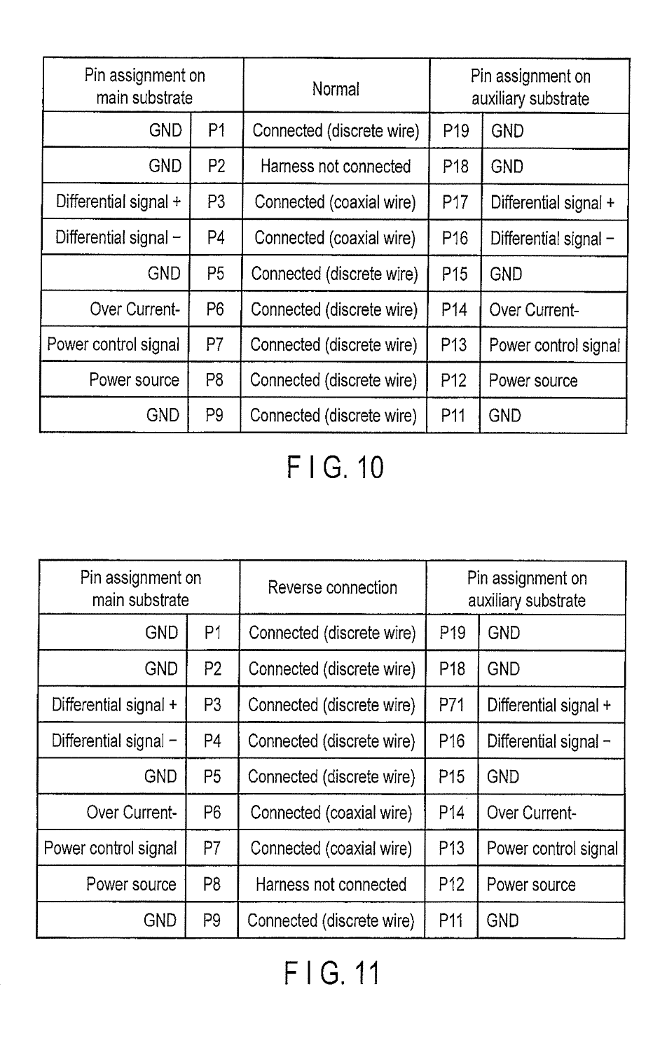

Even with the pin assignment shown in FIG. 10, it is easily seen that the wiring harness 103 is connected in reverse.

Signal terminals P1, P2, P5, P9 of the first terminal 301 are ground terminals, and are grounded. A pair of USB differential signals (differential signal + and differential signal −) are assigned to the two signal terminals P3, P4. An overcurrent signal (Overcurrent −) is assigned to signal terminal P6 of the first terminal 301. A power control signal (On# signal) output from the EC 402 is assigned to signal terminal P7 of the first terminal 301. A power source (electric power) is assigned to signal terminal P8 of the first terminal 301.

Signal terminals P11, P15, P18, P19 of the second terminal 302 are ground terminals, and are grounded. A pair of USB differential signals (differential signal + and differential signal −) are assigned to the two signal terminals P16, P17. An overcurrent signal (Overcurrent −) is assigned to signal terminal P14 of the second terminal 302. A power control signal (On# signal) output from the EC 402 is assigned to signal terminal P13 of the second terminal 302. A power source (electric power) is assigned to signal terminal P12 of the second terminal 302.

When the wiring harness 103 is connected normally, signal terminal P8 and signal terminal P12 are electrically connected. When the wiring harness 103 is connected in reverse, signal terminal P8 and signal terminal P12 are not electrically connected, as shown in FIG. 11.

Since a power source is not supplied to the auxiliary substrate 102 when the wiring harness 103 is installed in reverse, a USB device does not operate when placed into the USB connector 105 during a pre-shipment inspection. It is thereby easily seen that the wiring harness 103 is connected in reverse.

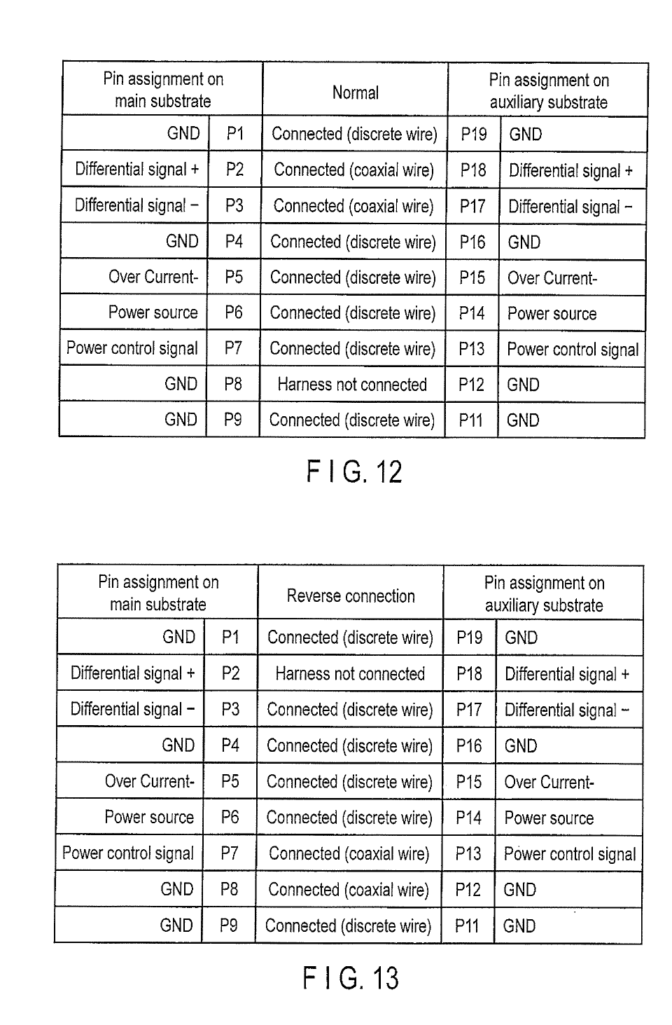

Even with the pin assignment shown in FIG. 12, it is easily seen that the wiring harness 103 is connected in reverse.

Signal terminals P1, P4, P8, P9 of the first terminal 301 are ground terminals, and are grounded. A pair of USB differential signals (differential signal + and differential signal −) are assigned to the two signal terminals 22, P3. An overcurrent signal (Overcurrent −) is assigned to signal terminal P5 of the first terminal 301. A power source (electric power) is assigned to signal terminal P6 of the first terminal 301. A power control signal (On# signal) output from the EC 402 is assigned to signal terminal P7 of the first terminal 301.

Signal terminals P11, P12, P16, P19 of the second terminal 302 are ground terminals, and are grounded. A pair of USB differential signals (differential signal and differential signal −) are assigned to the two signal terminals P17, P18. An overcurrent signal (Overcurrent −) is assigned to signal terminal P15 of the second terminal 302. A power control signal (On# signal) output from the EC 402 is assigned to signal terminal P13 of the second terminal 302. A power source (electric power) is assigned to signal terminal 214 of the second terminal 302.

When the wiring harness 103 is connected normally, signal terminal P2 and signal terminal P18 are electrically connected. When the wiring harness 103 is connected in reverse, signal terminal P2 and signal terminal P18 are not electrically connected, as shown in FIG. 13. When the wiring harness 103 is connected in reverse, the differential signals are not transmitted.

Since the differential signals are not transmitted when the wiring harness 103 is installed in reverse, a USB device does not operate when placed into the USB connector 105 during a pre-shipment inspection. It is thereby easily seen that the wiring harness 103 is connected in reverse.

In addition to the example described above, the pin assignment may be set such that signal terminals for transmitting audio signals are open when the wiring harness 103 is installed in reverse. Since the sound cannot be heard when the wiring harness 103 is installed in reverse, it is easily seen that the wiring harness 103 is connected in reverse.

The pin assignment may be set such that the signal terminals for transmitting video signals are open when the wiring harness 103 is installed in reverse. Since the video is not projected when the wiring harness 103 is installed in reverse, it is easily seen that the wiring harness 103 is connected in reverse.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

What is claimed is:

1. An electronic apparatus, comprising:
a first printed wiring board;
a first terminal on the first printed wiring board;
a second printed wiring board;
a second terminal on the second printed wiring board; and
a connection member configured to transmit signals between the first printed wiring board and the second printed wiring board, the connection member comprising a wire rod member comprising kinds of wire rods, a first connector capable of being connected to the first terminal and the second terminal, and a second connector capable of being connected to the first terminal and the second terminal, wherein
the signals are transmitted normally when the first connector is connected to the first terminal and the second connector is connected to the second terminal, and
at least one of the signals is not transmitted when the first connector is connected to the second terminal and the second connector is connected to the first terminal.

2. The apparatus of claim 1, wherein
the first printed wiring board comprises a controller configured to determine whether an overcurrent state is occurring in the second printed wiring board, to transmit a first signal to supply a power source when it is determined that the overcurrent state is not occurring, and to transmit a second signal to stop supply of the power source when it is determined that the overcurrent state is occurring,
the second wiring board comprises a current regulator module configured to control supply of the power source in response to the first signal and the second signal transmitted from the control module,
one of the wire rods is configured to transmit a power potential to measure the overcurrent state from the second printed wiring board when the first connector is connected to the first terminal and the second connector is connected to the second terminal, and
one of the wire rods is configured to electrically connect a ground of the second printed wiring board and the controller when the first connector is connected to the second terminal and the second connector is connected to the first terminal.

3. The electronic apparatus of claim 1, wherein
the first terminal comprises a preset number of first signal terminals,
the second terminal comprises a preset number of second signal terminals, and
the wiring harness comprises wire rods of a number less than the preset number at least by one.

4. An electronic apparatus, comprising:
a first printed wiring board;
a first terminal on the first printed wiring board,
a second printed wiring board;
a second terminal on the second printed wiring board; and
a connection member configured to transmit signals between the first printed wiring board and the second printed wiring board and to transmit electric power from the first printed wiring board to the second printed wiring board, the connection member comprising a wire rod member comprising kinds of wire rods; a first connector capable of being connected to the first terminal and the second terminal, and a second connector capable of being connected to the first terminal and the second terminal, wherein
the electric power is transmitted from the first printed wiring board to the second printed wiring board when the first connector is connected to the first terminal and the second connector is connected to the second terminal, and
the electric power is not transmitted from the first printed wiring board to the second printed wiring board when the first connector is connected to the second terminal and the second connector is connected to the first terminal.

5. The electronic apparatus of claim 4, wherein
the first terminal comprises a preset number of first signal terminals,
the second terminal comprises a preset number of second signal terminals, and
the wiring harness comprises wire rods of a number less than the preset number at least by one.
